(19) United States
(12) Patent Application Publication
(10) Pub. No.: US 2025/0183854 A1
(43) Pub. Date: Jun. 5, 2025

(54) SEMICONDUCTOR DEVICE HAVING IMPROVED NOISE FIGURE AND OPTIMIZED TRANSIENT RESPONSE

(71) Applicant: RichWave Technology Corp., Taipei City (TW)

(72) Inventors: Yu-Hsuan Chao, Taipei City (TW); Chih-Sheng Chen, Taipei City (TW)

(73) Assignee: RichWave Technology Corp., Taipei City (TW)

(21) Appl. No.: 18/396,722

(22) Filed: Dec. 27, 2023

(30) Foreign Application Priority Data
Dec. 1, 2023 (TW) 112146826

(51) Int. Cl. H03F 1/26; H03F 3/72

(52) U.S. Cl. CPC H03F 1/26; H03F 3/72; H03F 2200/294; H03F 2203/7206

(57) ABSTRACT

A semiconductor device includes a first set of transistors and a second set of transistors. The first set of transistors includes a first terminal, a second terminal, a control terminal and a bulk terminal, and the bulk terminal of the first set of transistors is floating. The second set of transistors includes a first terminal, a second terminal, a control terminal and a bulk terminal, and the first terminal, the second terminal and the control terminal of the second set of transistors being coupled to the first terminal, the second terminal and the control terminal of the first set of transistors, respectively. When the semiconductor device is in a steady state, the bulk terminal of the second set of transistors is decoupled from the bias terminal. When the semiconductor device is in a transient state, the bulk terminal of the second set of transistors is coupled to the bias terminal.

### TECHNICAL FIELD

The present invention relates to semiconductor devices, and in particular, to a semiconductor device having improved noise figure and optimized transient response for use in power amplifiers, low noise amplifiers, switch modules and so on.

### BACKGROUND

Semiconductor devices such as power amplifiers (PAS), low-noise amplifiers (LNAs) and switching modules may be implemented by various types of transistors. For example, an LNA plays a key role in many applications such as wireless communications, radars, and satellite communications, and may be used to amplify weak signals with reduced noise. In some applications, it is desired for the semiconductor devices to have improved noise figure and/or optimized transient response.

### SUMMARY

According to an embodiment of the invention, a semiconductor device includes a first set of transistors and a second set of transistors. The first set of transistors includes a first terminal, a second terminal, a control terminal and a bulk terminal, and the bulk terminal of the first set of transistors is floating. The second set of transistors includes a first terminal, a second terminal, a control terminal and a bulk terminal, and the first terminal, the second terminal and the control terminal of the second set of transistors are coupled to the first terminal, the second terminal and the control terminal of the first set of transistors, respectively. The bulk terminal of the second set of transistors is selectively electrically coupled or decoupled to a bias terminal. When the semiconductor device is operated in a steady state, the bulk terminal of the second set of transistors is electrically decoupled from the bias terminal. When the semiconductor device is operated in a transient state, the bulk terminal of the second set of transistors is electrically coupled to the bias terminal.

### BRIEF DESCRIPTION OF THE DRAWINGS

FIGS. 1-2 are circuit schematics of semiconductor devices according to various embodiments of the invention.

FIGS. 3-6 are layout schematics of semiconductor devices according to various embodiments of the invention.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

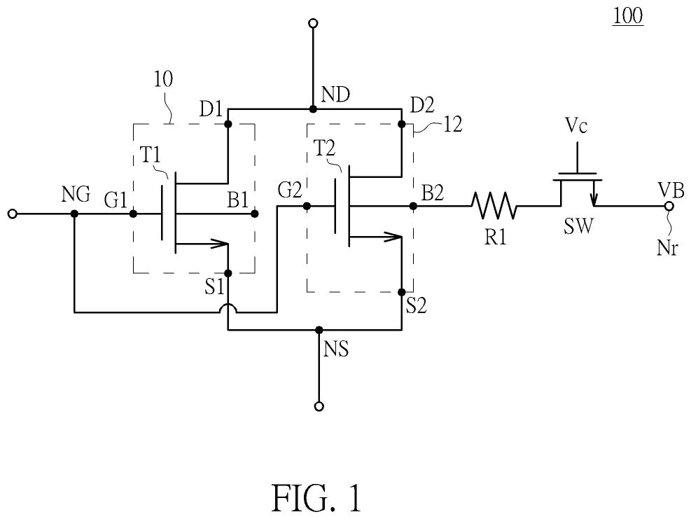

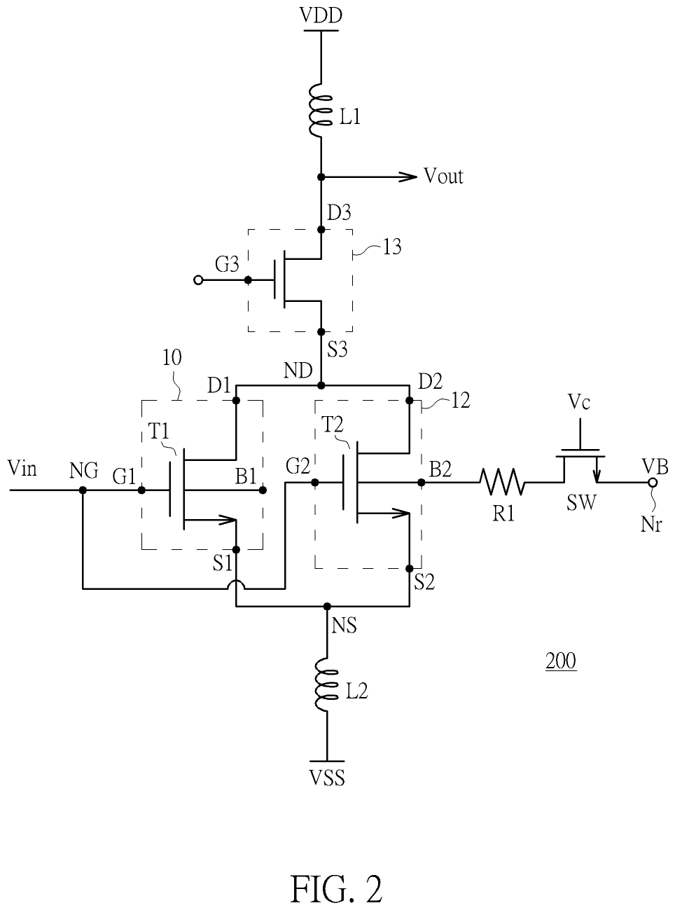

FIGS. 1-2 are circuit schematics of semiconductor devices 100 and 200 according to various embodiments of the invention.

In FIG. 1, the semiconductor device 100 may include a first set of transistors 10 and a second set of transistors 12. The first set of transistors 10 may include a first terminal D1, a second terminal S1, a control terminal G1, and a bulk terminal (also referred to as a body terminal) B1, and similarly, the second set of transistors 12 may include a first terminal D2, a second terminal S2, a control terminal G2, and a bulk terminal B2. The first terminal D2, the second terminal S2, and the control terminal G2 of the second set of transistors 12 are respectively coupled to the first terminal D1, the second terminal S1, and the control terminal G1 of the first set of transistors 10, thereby forming nodes ND, NS, and NG, respectively. In some embodiments, the bulk terminal B1 of the first set of transistors 10 may be floating, and the bulk terminal B2 of the second set of transistors 12 may be selectively coupled to a bias terminal Nr. Therefore, the first set of transistors 10 may be referred to as floating body transistors, and the second set of transistors 12 may be referred to as non-floating body transistors. In some embodiments, the second set of transistors 12 may also be referred to as body contact transistors or body tie transistors.

The first set of transistors 10 and/or the second set of transistors 12 may include field-effect transistors (FETs) or bipolar junction transistors (BJTs). In case of FETs, the first terminal of the transistors may be drain, the second terminal of the transistors may source, and the control terminal of the transistors may be gate. In case of BJTs, the first terminal of the transistors may collector, the second terminal of the transistors may be emitter, and the control terminal of the transistors may be base. For example, the semiconductor device 100 may be applicable to a low noise amplifier (LNA) as discussed below with reference to FIG. 2.

In FIG. 2, the semiconductor device 200 may include the first set of transistors 10, the second set of transistors 12, and a third set of transistors 13. The first set of transistors 10 and the second set of transistors 12 are arranged in a manner similar to the semiconductor device 100 shown in FIG. 1. The third set of transistors 13 may include a first terminal D3, a second terminal S3, and a control terminal G3, and may further include a bulk terminal (not shown). The second terminal S3 of the third set of transistors 13 may be coupled to the node ND, and the first terminal D3 may be configured to receive a system voltage VDD via another component (e.g., an inductor L1). In addition, the control terminal G3 of the third set of transistors 13 may be coupled to a bias circuit (not shown). In FIG. 2, the node NS may be configured to receive a reference voltage VSS via another component (e.g., an inductor L2). In some embodiments, the reference voltage VSS may be set at a fixed voltage level such as 0V.

In this embodiment, the semiconductor device 200 may be configured to receive an input signal Vin via the node NG and may provide an amplified output voltage Vout via the first terminal D3 of the third set of transistors 13. For example, both the input signal Vin and the output voltage Vout may be radio frequency signals. The applications of the semiconductor device 200 presented here are illustrative and not restrictive. In other embodiments, the semiconductor device 200 may also be implemented in power amplifiers, switch modules and other devices.

In the above embodiment, the semiconductor device 100 and/or the semiconductor device 200 may operate in a transient state and a steady state, so as to provide improved the noise figure and/or desired the transient response.

Returning to FIG. 1, the semiconductor device 100 may further include a resistive component R1 and a switching device SW. The resistive component R1 may include a first terminal coupled to the bulk terminal B2 of the second set of transistors 12, and a second terminal coupled to the switching device SW. The switching device SW may include a first terminal coupled to the second terminal of the resistive component R1, a second terminal coupled to the bias terminal Nr, and a control terminal. The bias terminal Nr may be used to provide a bias signal VB. In this embodiment, the resistance of the resistor R1 may be, for example, about 100 kΩ, so as to substantially reduce undesirable noise coupling. The bias signal VB may be set at a fixed voltage such as 0V. Further, the control terminal of the switching device SW may be configured to receive a control voltage Vc to control the switching device SW to be turned on or off. The bulk terminal B2 of the second set of transistors 12 may be selectively electrically connected or electrically disconnected from the bias terminal Nr by using the switching device SW. The embodiment provides an illustrative configuration of the resistive component R1 and the switching device SW. Nevertheless, the scope of the invention is not limited to this specific configuration. In some embodiments, positions of the resistive component R1 and the switching device SW may be exchanged.

As described above, the semiconductor devices 100/200 may operate in a steady state and/or a transient state. In the steady state, the semiconductor devices 100/200 may provide improved noise figure, and in the transient state, the semiconductor devices 100/200 may provide desired transient response.

Specifically, in FIG. 1, when the semiconductor device 100 operates in the steady state, the switching device SW may be turned off based on the control voltage Vc, and thus the bulk terminal B2 of the second set of transistors 12 may be disconnected from (alternatively, decoupled from) the bias terminal Nr. Therefore, the bulk terminal B2 of the second set of transistors 12 may be floating. In such a case, the bulk terminal B1 of the first set of transistors 10 and the bulk terminal B2 of the second set of transistors 12 are both floating, so as to provide improved noise figure, and the noise in the output signal Vout may be reduced accordingly. Further, when the operation state of the semiconductor device 100 is changed (that is, the semiconductor device 100 is in a transient state), the switching device SW may be turned on based on the control voltage Vc, and thus the bulk terminal B2 of the second set of transistors 12 may be connected to (alternatively, coupled to) the bias terminal Nr. Therefore, the bulk terminal B2 of the second set of transistors 12 may receive the bias signal VB provided via the bias terminal Nr. In such a case, the bulk terminal B2 of the second set of transistors 12 may be tied at a voltage level, and the semiconductor device 100 may provide a fast transient response as a result, such that the state change of the semiconductor device 100 may be speed up. In the above embodiment, regardless of the semiconductor device 100 being in a steady state or a transient state, the bulk terminal B1 of the first set of transistors 10 is floating. The explanation therefor may be found below.

In some embodiments, the first set of transistors 10, the second set of transistors 12, and/or the switching device SW may be, but are not limited to, N-type metal-oxide-semiconductor field-effect transistors (MOSFETs). In other embodiments, the first set of transistors 10, the second set of transistors 12, and/or the switching device SW may also be implemented by P-type MOSFETs or other types of transistors.

While FIG. 1 shows that the first set of transistors 10 includes one first transistor T1 and the second set of transistors 12 includes one second transistor T2, those skilled in the art may modify the quantities of transistors in the first set of transistors 10 and/or in the second set of transistors 12 according to the actual requirement without deviating from the principle of the present invention. In some embodiments, the first set of transistors 10 may include m first transistors T1, and the second set of transistors 12 may include n second transistors T2, and m and n may be integers. In other embodiments, m may be equal to or greater than n. For example, m and n may be configured as m:n=200:1, 199:1, 100:1, 99:1, 49:1, 3:1, 2:1 or 1:1, as further discussed below. It should be understood that the numerical values herein are given for illustrative purpose and may be approximate values, for example, they may fall within a range of +10% of the given value.

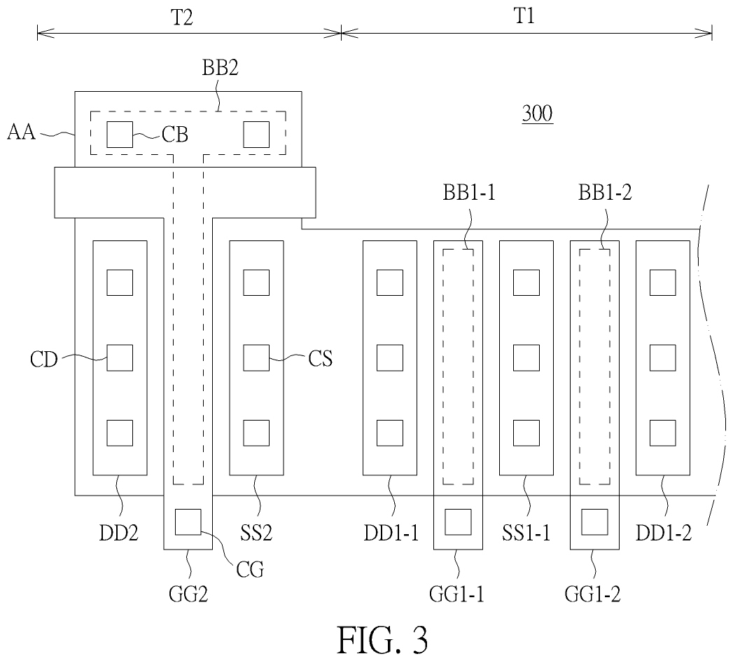

FIGS. 3-6 are layout schematics of semiconductor devices 300-600 according to various embodiments of the invention. In some embodiments, various transistors may be implemented by MOSFETs, and each transistor may be defined to include a drain region, a source region, a gate region, and a bulk region. In a layout view, the gate region may be located between the drain region and the source region, and two adjacent transistors may share a drain region (or a source region) there-between. In a cross-sectional view, the bulk region may be located below the gate region. The transistors may be fabricated by many processes such as the silicon on insulator (SOI) process.

In FIG. 3, the semiconductor device 300 includes the first set of transistors 10 and the second set of transistors 12, both are disposed substantially in an active area AA. In some applications, the active area AA is also referred to as an oxide diffusion region ODr. For description, the active area AA may be used below.

The first set of transistors 10 may include a plurality of first transistors T1 (e.g., 199 first transistors T1), and the second set of transistors 12 may include one second transistor T2. For example, the second transistor T2 may include a drain region DD2, a source region SS2, a gate region GG2, and a bulk region BB2 below the gate region GG2. One of the plurality of first transistors T1 may include a drain region DD1-1, a source region SS1-1, a gate region GG1-1 located between the drain region DD1-1 and the source region SS1-1, and a bulk region BB1-1 located below the gate region GG1-1. Another of the plurality of first transistors T1 may include a drain region DD1-2, a source region SS1-1, a gate region GG1-2 located between the drain region DD1-2 and the source region SS1-1, and a bulk region BB1-2 located below the gate region GG1-2. As shown, two adjacent ones of the plurality of first transistors T1 may share, but are not limited to, the source region SS1-1. In other embodiments, two adjacent ones of the plurality of the first transistors T1 may share a drain region.

In above embodiments, various drain regions (e.g., DD1-1 and DD1-2) of the plurality of first transistors T1 may be coupled together via a first metal layer (not shown). For description, the various drain regions of the plurality of first transistors T1 may be collectively referred to as a drain region DD1. Similarly, various source regions (e.g., SS1-1 and SS1-2) of the plurality of first transistors T1 may be coupled together via a second metal layer, and may be collectively referred to as a source region SS1. Various gate regions (e.g., GG1-1 and GG1-2) of the plurality of first transistors T1 may be coupled together via a third metal layer, and may be collectively referred to as a gate region GG1.

In some embodiments, for example, the second transistor T2 may further include a drain contact CD, a source contact CS, and a gate contact CG to respectively couple the drain region DD2, the source region SS2, and the gate region GG2 to other components (e.g., metal layers). The second transistor T2 may additionally include a bulk contact CB to couple the bulk region BB2 to other components, e.g., to couple the bulk region BB2 to the ground. Furthermore, the bulk region of the first transistor T1 may be floating, and the first transistor T1 may therefore not include a bulk contact. The positions and quantities of contacts depicted in FIG. 3 are merely for illustrative purposes and are not intended to limit the scope of the present invention. Those skilled in the art may adjust the quantities of contacts at suitable locations according to actual needs without deviating from the principle of the invention.

In above embodiments, with reference to FIG. 1 or 2, the drain region DD2 of the second transistor T2 may be coupled to the drain region DD1 of the first transistor T1 to form the node ND described above. The source region SS2 of the second transistor T2 may be coupled to the source region SS1 of the first transistor T1 to form the node NS. Furthermore, the node NS may be further coupled to a reference voltage terminal to receive, for example, the reference voltage VSS. The gate region GG2 of the second transistor T2 may be coupled to the gate region GG1 of the first transistor T1 to form the node NG.

FIG. 3 illustrates an embodiment where min may be about 199:1. In the embodiment, the quantity m of the first transistor T1 may be 199, and the quantity n of the second transistor T2 may be 1. As shown, the one second transistor T2 is disposed at a side position of the plurality of first transistors T1.

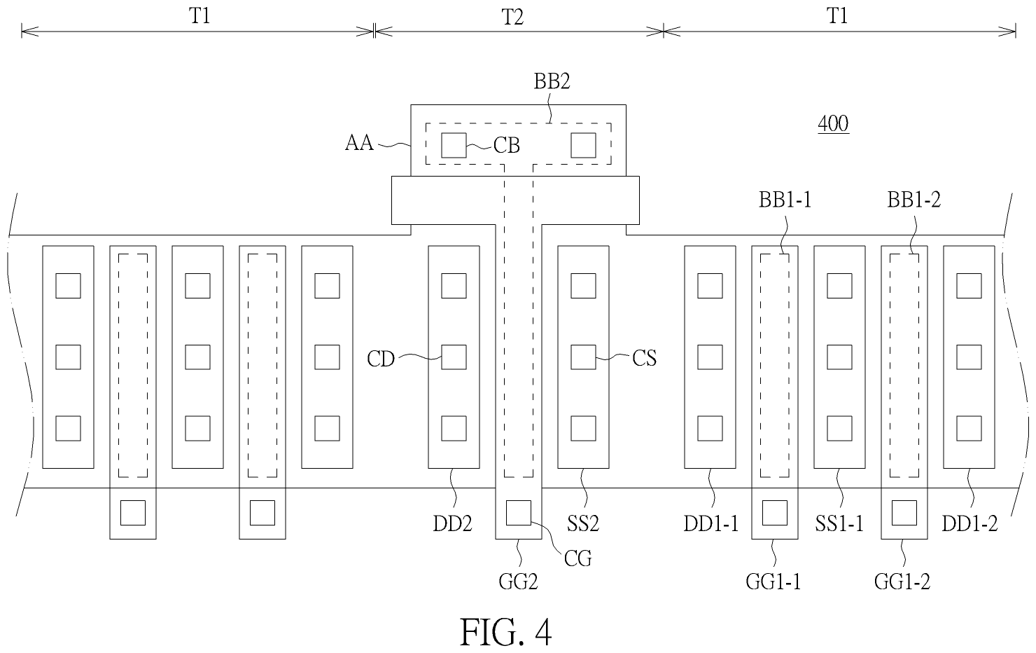

However, the present invention is not limited thereto and in other embodiments, the one second transistor T2 may disposed at a middle position of the plurality of first transistors T1, that is, relative to the one second transistor T2 at the middle, about half of the plurality of first transistors T1 are arranged on the left and the other half on the right, as shown in the semiconductor device 400 in FIG. 4.

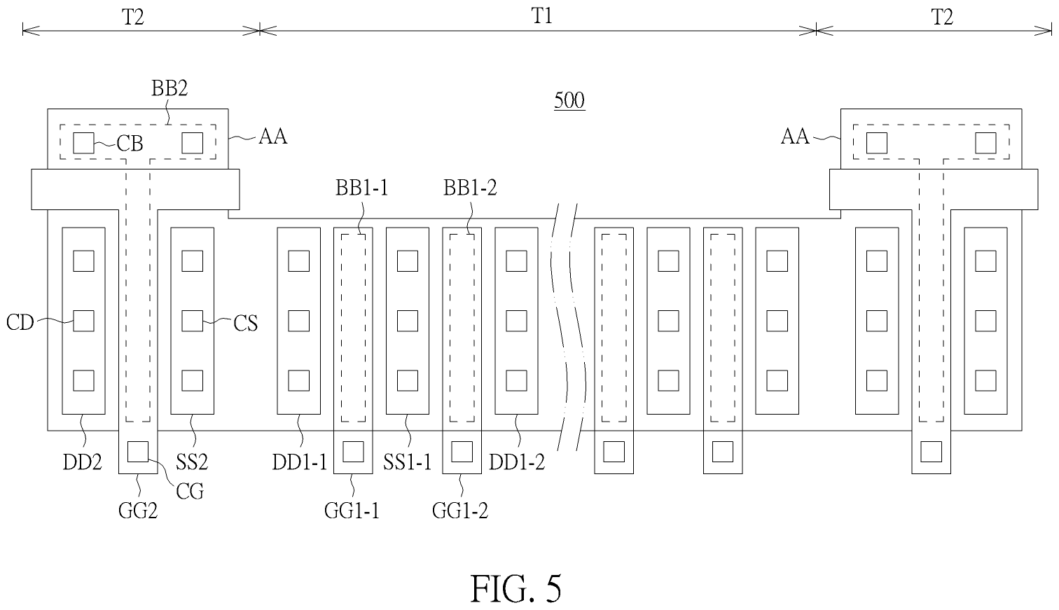

Referring to FIG. 5, the semiconductor device 500 is substantially similar to the semiconductor device 300. The main difference lies in that the second set of transistors 12 in the semiconductor device 500 include two second transistors T2, that is, n=2. As shown, one of the two second transistors T2 is disposed at the first side (e.g., left) position of the plurality of first transistors T1, and the other of the two second transistors T2 is disposed at the second side (e.g., right) of the plurality of first transistors T1. In other words, the plurality of first transistors T1 are all disposed between the two second transistors T2.

In other embodiments, for example, the first set of transistors 10 may include a plurality of first transistors T1, and the second set of transistors 12 may include a plurality of second transistors T2. Various ones of the plurality of second transistors T2 may be evenly allocated relative to the plurality of first transistors T1. For example, the quantities of the first transistors T1 between every two adjacent second transistors T2 may be equal. For example, the second set of transistors 12 may include three second transistors T2, and they may respectively be positioned at two side positions and a middle position relative to the plurality of first transistors T1.

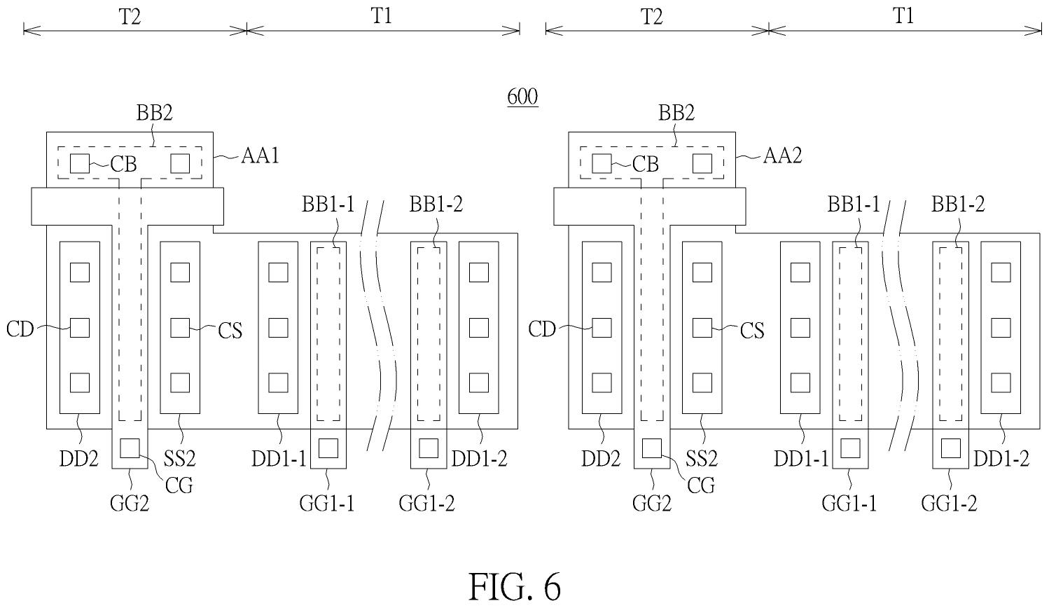

Referring to FIG. 6, the semiconductor device 600 includes the first set of transistors 10 and the second set of transistors 12 substantially disposed in a first active area AA1. The semiconductor device 600 may further include a first set of transistors 10′ and a second set of transistors 12′ substantially disposed in a second active area AA2. The configurations of the first set of transistors 10′ and the second set of transistors 12′ in the second active area AA2 may be respectively similar to the first set of transistors 10 and the second set of transistors 12 shown in FIG. 3, and explanation therefor may be found in the preceding paragraphs and will not be repeated here.

In at least one embodiment, a semiconductor device includes a first set of transistors and a second set of transistors, a bulk terminal of the first set of transistors may be floating, and a bulk terminal of the second set of transistors may be selectively coupled to a bias terminal. The first set of transistors with the floating bulk terminal may be used to provide improved noise figures. The second set of transistors with the bulk terminal non-floated may provide desired transient response in a transient state. For example, the noise figure of the first set of transistors may be characterized as 1.5 dB, and the noise figure of the second set of transistors may be characterized as 3 dB. According to at least one embodiment of the present invention, further improved noise figure and desired transient response may be provided via proper operations of the first set of transistors and/or the second set of transistors.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device comprising:
a first set of transistors comprising a first terminal, a second terminal, a control terminal, and a bulk terminal, wherein the bulk terminal of the first set of transistors is floating; and
a second set of transistors comprising a first terminal, a second terminal, a control terminal, and a bulk terminal, wherein the first terminal, the second terminal, and the control terminal of the second set of transistors being coupled to the first terminal, the second terminal, and the control terminal of the first set of transistors, respectively, and wherein the bulk terminal of the second set of transistors is selectively electrically connected to or disconnected from a bias terminal;
wherein when the semiconductor device is in a steady state, the bulk terminal of the second set of transistors is electrically disconnected from the bias terminal;
when the semiconductor device is in a transient state, the bulk terminal of the second set of transistors is electrically connected to the bias terminal.

2. The semiconductor device of claim 1, further comprising:
a switching device coupled between the bulk terminal of the second set of transistors and the bias terminal, wherein:
when the semiconductor device is in the steady state, the switching device is turned off; and
when the semiconductor device is in the transient state, the switching device is turned on and the bulk terminal of the second set of transistors receives a bias signal from the bias terminal.

3. The semiconductor device of claim 2, further comprising:
a resistive component coupled between the bulk terminal of the second set of transistors and the switching device, or coupled between the switching device and the bias terminal.

4. The semiconductor device of claim 3, wherein the resistance of the resistive component is 100 k ohms.

5. The semiconductor device of claim 1, wherein the first set of transistors and the second set of transistors are disposed in a first active area.

6. The semiconductor device of claim 1, wherein the semiconductor device is used in a power amplifier, a low noise amplifier, or a switch module.

7. The semiconductor device of claim 1, wherein the first set of transistors comprises m first transistors, and the second set of transistors comprises n second transistors, m and n being different integers.

8. The semiconductor device of claim 7, wherein m is greater than n.

9. The semiconductor device of claim 7, wherein m:n=200:1, 199:1, 100:1, 99:1, 49:1, 3:1, 2:1 or 1:1.

10. The semiconductor device of claim 7, wherein when n=1, a second transistor of the second set of transistors is disposed at one side position of the m first transistors, or at a middle position of the m first transistors.

11. The semiconductor device of claim 7, wherein when n=2, two second transistors of the second set of transistors are respectively disposed at a first side position and a second side position of the m first transistors.

12. The semiconductor device of claim 7, wherein when n>1, the n second transistors of the second set of transistors are evenly allocated relative to the m first transistors.

13. The semiconductor device of claim 1, further comprising:
a third set of transistors comprising a first terminal, a second terminal, a control terminal, and a bulk terminal, wherein the bulk terminal of the third set of transistors is floating; and
a fourth set of transistors comprising a first terminal, a second terminal, a control terminal, and a bulk terminal, wherein the first terminal, the second terminal, and the control terminal of the fourth set of transistors being coupled to the first terminal, the second terminal, and the control terminal of the third set of transistors, respectively, wherein the bulk terminal of the fourth set of transistors is selectively electrically connected to or disconnected from the bias terminal;
wherein the first set of transistors and the second set of transistors are disposed in a first active area, and the third set of transistors and the fourth set of transistors are disposed in a second active area.
